(19) United States
(12) Patent Application Publication
(10) Pub. No.: US 2025/0300427 A1
(43) Pub. Date: Sep. 25, 2025

(54) METHOD FOR FORMING INTERCONNECT LAYER

(71) Applicant: IMEC VZW, Leuven (BE)

(72) Inventors: Negin Golshani, Tienen (BE); Peter Verheyen, Nijlen (BE); Joris Van Campenhout, Leuven (BE)

(21) Appl. No.: 19/081,059

(22) Filed: Mar. 17, 2025

(30) Foreign Application Priority Data
Mar. 22, 2024 (EP) 24165515.8

(51) Int. Cl. H01S 5/042; G01R 31/26

(52) U.S. Cl. CPC H01S 5/04256; G01R 31/2635; H01S 5/04252

(57) ABSTRACT

The disclosure relates to a method for forming electrical connections in devices with a top surface having an electrical path and a cavity for a die. The method includes creating a (e.g., substantially) continuous interconnect layer from the cavity's bottom to the electrical path, overcoming topographical hurdles. The method also relates to a corresponding device.

### CROSS-REFERENCE TO RELATED APPLICATIONS

The present application is a non-provisional patent application claiming priority to European Patent Application No. 24165515.8, filed Mar. 22, 2024, the contents of which are hereby incorporated by reference.

### FIELD OF THE DISCLOSURE

The present disclosure pertains to the field of semiconductor device fabrication, such as methods and structures for forming interconnects.

### BACKGROUND

The field of electrical and electro-optical testing in high aspect ratio structures, particularly those containing stacked die, is a complex and evolving area of technology. As electronic devices become increasingly miniaturized and complex, the need for efficient and reliable interconnection methods grows. The integration of multiple dies within a single package, often referred to as 3D packaging, presents unique challenges for testing and interconnection.

Accessing and testing the electrical connections of dies within cavities of electronic or opto-electronic devices may present challenges.

Traditional methods to form these electrical connections, such as wire bonding (see FIG. 1), have limitations. The common use of copper (Cu) for forming electrical connections, favored for its low electrical resistivity, may be susceptible to oxidation during the wire bonding process, potentially compromising the electrical connection integrity. The bonding process further complicates matters when tin (Sn) is used, as melting Sn may lead to Sn squeezing out and inadvertently forming connections with the copper in the electrical connection, raising the risk of short circuits or other failures. Accurately measuring the bonded device may be a daunting task due to the complex internal structure and the constrained space available for testing probes or measurement instruments. Hence, these methods typically necessitate a large cavity (see FIG. 2) within the structure to facilitate the bonding process and provide pad accessibility, which introduces several technical complexities. Additionally, wire bonding or creating a (e.g., significantly) large cavity not only complicates and escalates the cost of the manufacturing process but also heightens the risk of inflicting damage to the delicate internal components during the bonding and testing phases.

These challenges highlight the need for improved methods for forming electric connections that may accommodate the intricate designs of modern electronic devices. The industry continues to seek advancements that may streamline the manufacturing process, enhance the reliability of the connections, and facilitate easier testing of the final product. Despite the progress made in recent years, there is still a need for further advancements in the field to address these challenges effectively.

### SUMMARY

An object of the present disclosure is to facilitate the formation and testing of electrical connections in electro-optic or electronic devices. This objective may be accomplished by a method for forming electrical connections in an electro-optic or electronic device according to the disclosure.

In a first aspect, the present disclosure relates to a method for forming electrical connections in an electro-optic or electronic device including a top surface exposing an electrical path, and a cavity in the top surface. The cavity configured to house a die. The electrical connections may be suitable for connecting the electrical path and the die. Forming the electrical connections includes forming a (e.g., substantially continuous) interconnect layer extending from a bottom of the cavity, across (e.g., any) topographical features, to the electrical path.

In example embodiments, the continuous interconnect layer may include an electrically conductive protection layer suitable to prevent disconnection in the continuous interconnect layer during a wet etch process. This embodiment maintains the integrity of the interconnect layer during processing.

In example embodiments, the electrically conductive protection layer may include a metal with wet etching selectivity to the conductive material used to form the continuous interconnect layer. For instance, if this conductive material is copper, the electrically conductive protection layer may include a metal with wet etching selectivity to copper. This embodiment offers selective etching, which preserves the integrity of the continuous interconnect layer.

In example embodiments where the continuous interconnect layer is made of copper, the metal may be selected from nickel and cobalt. This embodiment uses metals that provide (e.g., effective) protection with good etching selectivity to copper.

In example embodiments, the protection layer may have a thickness of from 0.1 μm to 3.0 μm, or from 0.2 μm to 2.0 μm, or from 0.3 μm to 1.0 μm, or from 0.3 μm to 0.7 μm. This embodiment provides adequate protection without (e.g., significantly) impacting the overall conductivity of the interconnect layer.

In example embodiments, the method may further include (e.g., the step of) depositing a seed layer on the device prior to forming the continuous interconnect layer, and may include (e.g., the step of) etching the seed layer after the forming of the electrical connections to leave the seed layer under the electrical connections but remove the seed layer everywhere else. This embodiment allows for precise control of where the interconnect layer is formed. When this embodiment is used, using a protection layer better preserves the electrical connections during the removal of the seed layer.

In example embodiments, the method may further include depositing a barrier layer on the device before depositing the seed layer, and wherein the step of etching the seed layer is followed by a step of etching the barrier layer so as to leave the barrier layer under the electrical connections but remove the barrier layer everywhere else. This embodiment prevents unwanted diffusion between the interconnect layer and underlying materials.

In example embodiments, the barrier layer may be configured to prevent diffusion between the continuous interconnect layer and underlying materials. This embodiment prevents material intermixing that could degrade device performance.

In example embodiments, the barrier layer may be made (e.g., provided in the form) of TiW, TiN, or TaN. This embodiment uses materials known for their (e.g., effective) barrier properties.

In example embodiments, the method may further include (e.g., the step of) forming connection bumps for the die on the continuous interconnect layer on the bottom of the cavity. This embodiment facilitates reliable electrical connections between the die and the interconnect layer.

In example embodiments, the method may further include (e.g., the step of) etching the seed layer, and if present the barrier layer, after the formation of the connection bumps. This embodiment allows for a single seed layer etch, improving process efficiency.

In example embodiments, forming the connection bumps may include forming a patterned mask having openings exposing the continuous interconnect layer only where the connection bumps will be formed, followed by electroplating a metal through the openings. This embodiment provides precise bump placement and size control.

In example embodiments, the material of the connection bumps may include at least one of tin, silver, bismuth, indium, copper, cobalt, and gold. This embodiment selects bump materials that are suitable for various bonding temperatures and mechanical properties.

In example embodiments, the electrical path may be configured to provide (e.g., enable) electrical or electro-optical tests of the die. This embodiment facilitates testing of the die without the need for additional connections.

In example embodiments, the method may include using a lift-off process for forming the continuous interconnect layer, wherein the lift-off process involves depositing the continuous interconnect layer material on a patterned resist and then removing the resist to leave the continuous interconnect layer (e.g., only) in desired locations (e.g., where the resist was not present). This embodiment offers a simpler process for forming the interconnect layer.

In example embodiments, the top surface may include therein a number of cavities for housing a die. The number of cavities form a pattern. The method further includes providing a carrier substrate removably attached to a same number of dies arranged in this same pattern, physically contacting the dies, attached to the carrier substrate, with the electronic device in a way that each die is housed in a cavity and connects electrically with the continuous interconnect layer present at the bottom of the cavity. The method includes detaching the carrier substrate from the dies. This embodiment provides (e.g., efficient) die placement and bonding in a patterned array.

In example embodiments, the cavity may be suitable for laterally housing a die. In example embodiments, the width of the cavity may at most be 40% larger than the width of the die. For example, the width of the cavity may be from 5 μm to 1000 μm, such as from 50 to 950 μm, from 100 to 900 μm, or from 200 to 850 μm. In example embodiments, the length of the cavity may be from 10 μm to 5.0 mm, such as from 100 μm to 4.5 mm, from 200 μm to 4.0 mm, or from 400 μm to 3.5 mm. In example embodiments, the height of the cavity may be from 20 μm to 100 μm.

Any element of the first aspect may be correspondingly described in the second aspect.

In a second aspect, the present disclosure relates to an electro-optic or electronic device including a top surface exposing an electrical path, a cavity in the top surface for housing a die, and a (e.g., substantially continuous) interconnect layer extending from a bottom of the cavity, across any topographical features, to the electrical path.

In example embodiments, the continuous interconnect layer may include a protection layer including a metal with wet etching selectivity to the material making the continuous interconnect layer, e.g. copper. This embodiment provides protecting the interconnect layer during processing.

In example embodiments, the material making the continuous interconnect layer may be copper and the metal may be nickel or cobalt. This embodiment uses metals that provide (e.g., effective) protection with (e.g., good) etching selectivity.

In example embodiments, the protection layer may have a thickness of from 0.1 μm to 3.0 μm, or from 0.2 μm to 2.0 μm, or from 0.3 μm to 1.0 μm, or from 0.3 μm to 0.7 μm. This embodiment provides adequate protection without significantly impacting the overall conductivity of the interconnect layer.

In example embodiments, the device may further include a barrier layer between the continuous interconnect layer and underlying materials. This embodiment prevents unwanted diffusion between the interconnect layer and underlying materials.

In example embodiments, the barrier layer may include or consist of TiW, TiN, or TaN. This embodiment uses materials known for their (e.g., effective) barrier properties.

In example embodiments, the device may further include connection bumps for the die on the continuous interconnect layer on the bottom of the cavity. This embodiment creates reliable electrical connections between the die and the interconnect layer.

In example embodiments, the material of the connection bumps may include at least one of tin, silver, bismuth, indium, copper, cobalt, and gold. This embodiment selects bump materials that are suitable for various bonding temperatures and mechanical properties.

In example embodiments, the electrical path may be configured to provide electrical or electro-optical tests of the die. These electrical or electro-optical tests are typically tests of the embedded die and are performed from the top surface. This embodiment facilitates testing of the die without the need for additional connections.

Elements of the second aspect may be as correspondingly described in the first aspect.

Example embodiments of the present disclosure facilitate the connection between a housed die and the electrical path without the need for wire bonding or large cavities. Example embodiments of the present disclosure provide for the continuous interconnect layer may to include an electrically conductive protection layer, such as nickel or cobalt, which may be suitable to prevent disconnection during a wet etch process, thus enhancing the reliability of the electrical connections. The present disclosure provides that the protection layer may be applied with a thickness that does not (e.g., significantly) impact the overall resistance of the interconnect layer, thereby maintaining the electrical performance while providing protection.

Moreover, example embodiments of the present disclosure provide that the electrical path may be configured to provide electrical or electro-optical tests of the die from the top surface, simplifying the testing process and eliminating the need for large cavities or complex wire bonding procedures.

Furthermore, example embodiments of the present disclosure provide that a carrier substrate may be used to facilitate the alignment and attachment of a plurality of dies to the device, with the dies arranged in a pattern that corresponds to a pattern of cavities on the device, thereby streamlining the assembly process for devices with multiple dies.

In summary, example embodiments of the present disclosure provide that the described method and device offer a streamlined, reliable, and efficient approach to forming electrical connections in electro-optic or electronic devices, which may (e.g., significantly) improve the manufacturing process and the performance of the resulting devices.

Aspects of the disclosure are set out in the accompanying claims. Features from the dependent claims may be combined with features of the independent claims and with features of other dependent claims as appropriate.

The above and other characteristics, and features of the present disclosure may become apparent from the following detailed description, taken in conjunction with the accompanying drawings, which illustrate, by way of example, the principles of the disclosure. This description is for the sake of example, without limiting the scope of the disclosure. The reference figures below refer to the attached drawings.

### BRIEF DESCRIPTION OF THE FIGURES

The above, as well as additional, features will be better understood through the following illustrative and non-limiting detailed description of example embodiments, with reference to the appended drawings.

FIG. 1 is a cross-sectional view of a prior art device showing wire connections for testing on the top surface.

FIG. 2 is a cross-sectional view of a prior art device showing direct testing in a large cavity housing the die.

FIG. 3 is a cross-sectional view of an embodiment of the disclosure with testing accessible from the top surface electrical connections.

FIG. 4 is a side view of the disclosure showing multiple cavities prepared for die attachment, and dies being lowered therein.

FIG. 5 is a sequence of side views of the disclosure demonstrating the alignment and attachment process of dies on a patterned substrate to the device's cavities, including the detachment of the substrate.

FIGS. 6A, 6B, 6C, 6D, 6E, 6F, 6G, 6H, and 6I are cross-sectional views of a first embodiment of the disclosure without an electrically conductive protection layer.

FIGS. 7A, 7B, 7C, 7D, 7E, 7F, 7G, 7H, and 7I are cross-sectional views of another embodiment of the disclosure with an electrically conductive protection layer.

FIG. 8 is a scanning microscope image of an electrical connection in a semiconductor device according to an embodiment of the present disclosure, and a defective part of the electrical connection is shown.

FIG. 9 is a scanning microscope image of an electrical connection in a semiconductor device according to another embodiment of the present disclosure, where a protective coating is used on top of the continuous interconnect layer.

In the different figures, the same reference signs refer to the same or analogous elements.

The figures are schematic, not necessarily to scale, and generally show parts which elucidate example embodiments, wherein other parts may be omitted or merely suggested.

### DETAILED DESCRIPTION

Example embodiments will now be described more fully hereinafter with reference to the accompanying drawings. That which is encompassed by the claims may, however, be embodied in many different forms and should not be construed as limited to the embodiments set forth herein; rather, these embodiments are provided by way of example. Furthermore, like numbers refer to the same or similar elements or components throughout.

The present disclosure will be described with respect to particular embodiments and with reference to the drawings but the disclosure is not limited thereto but only by the claims. The drawings described are schematic and are non-limiting. In the drawings, the size of some of the elements may be exaggerated and not drawn on scale for illustrative purposes. The dimensions and the relative dimensions do not correspond to actual reductions to practice of the disclosure.

The terms first, second, third and the like in the description and in the claims, are used for distinguishing between similar elements and not necessarily for describing a sequence, either temporally, spatially, in ranking or in any other manner. It is to be understood that the terms used are interchangeable under appropriate circumstances and that the embodiments of the disclosure described herein are capable of operation in other sequences than described or illustrated herein.

Moreover, the terms top and over and the like in the description and the claims are used for descriptive purposes and not necessarily for describing relative positions. It is to be understood that the terms used are interchangeable under appropriate circumstances and that the embodiments of the disclosure described herein are capable of operation in other orientations than described or illustrated herein.

The term “comprising”, also used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be interpreted as being limited to devices consisting only of components A and B. It means that with respect to the present disclosure, the only relevant components of the device are A and B. The term “comprising” therefore covers the situation where (e.g., only) the stated features are present and the situation where these features and one or more other features are present. The word “comprising” according to the disclosure therefore also includes as one embodiment that no further components are present. When the word “comprising” is used to describe an embodiment in this application, it is to be understood that an alternative version of the same embodiment, wherein the term “comprising” is replaced by “consisting of”, is also encompassed within the scope of the present disclosure.

Similarly, the term “coupled” should not be interpreted as being restricted to direct connections only. The terms “coupled” and “connected”, along with their derivatives, may be used. It should be understood that these terms are not intended as synonyms for each other. Thus, the scope of the expression “a device A coupled to a device B” should not be limited to devices or systems wherein an output of device A is directly connected to an input of device B. It means that a path exists between an output of A and an input of B which may be a path including other devices or means. “Coupled” may mean that two or more elements are either in direct physical or electrical contact, or that two or more elements are not in direct contact with each other but yet still co-operate or interact with each other.

Reference throughout this specification to “one embodiment” or “an embodiment” means that a (e.g., particular) feature, structure or characteristic described in connection with the embodiment is included in at least one embodiment of the present disclosure. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly, in the description of example embodiments of the disclosure, various features of the disclosure are sometimes grouped together in a single embodiment, figure, or description thereof for the purpose of streamlining the disclosure and aiding in the understanding of one or more of the various aspects. This method of disclosure, however, is not to be interpreted as reflecting an intention that the claimed disclosure requires more features than are (e.g., expressly) recited in each claim. Rather, as the following claims reflect, aspects may lie in less than all features of a single foregoing disclosed embodiment. Thus, the claims following the detailed description are hereby expressly incorporated into this detailed description, with each claim standing on its own as a separate embodiment of this disclosure.

Furthermore, while some embodiments described herein include some but not other features included in other embodiments, combinations of features of different embodiments are meant to be within the scope of the disclosure, and form different embodiments, as would be understood by those in the art. For example, in the following claims, any of the claimed embodiments may be used in any combination.

Furthermore, some of the embodiments are described herein as a method or combination of elements of a method that may be implemented by a processor of a computer system or by other means of carrying out the function. Thus, a processor with the necessary instructions for carrying out such a method or element of a method forms a means for carrying out the method or element of a method. Furthermore, an element described herein of an apparatus embodiment is an example of a means for carrying out the function performed by the element for the purpose of carrying out the disclosure.

In the description provided herein, numerous details are set forth. However, it is understood that embodiments of the disclosure may be practiced without these details. In other instances, well-known methods, structures and techniques have not been shown in detail in order not to obscure an understanding of this description.

The following terms are provided to aid in the understanding of the disclosure.

As used herein, and unless otherwise specified, the term “electrical connections” refers to conductive pathways or structures including a continuous interconnect layer that provide the flow of electrical current between two or more points within an electro-optic or electronic device, and in particular between a die and an electrical path for testing the die.

As used herein, and unless otherwise specified, the term “continuous interconnect layer” refers to a single, (e.g., substantially) uninterrupted layer of conductive material that provides an electrical connection between two or more points within an electro-optic or electronic device, and in particular between a die and an electrical path for testing the die. The continuous interconnect layer extends from a bottom of the cavity, runs along and in physical contact with the bottom and a sidewall of the cavity, across (e.g., any) topographical features of the device separating the start of the continuous interconnect layer and its end, where it electrically connects to the electrical path. This layer is continuous in the sense that it does not have breaks or gaps that would impede electrical conductivity. Examples of embodiments include a metal layer that spans across the surface of a substrate, connecting different components or regions, such as a die and an electrical path, without interruption. The continuous interconnect layer may be deposited by physical vapor deposition (PVD), chemical vapor deposition (CVD), electroplating, or electroless plating. For example, continuous interconnect layer is deposited by electroless plating.

In an example embodiment, the electro-optic or electronic device (102) may be a device for integrating at least one die. The die can, for instance, be a laser diode, such as a hybrid laser diode. The device may include an optical path (122) for interacting optically with the laser diode, when the laser diode is connected to the electrical connection (100).

As used herein, and unless otherwise specified, the term “electrically conductive protection layer” refers to a layer of material that is capable of conducting electricity and is applied to protect underlying layers or structures during processing steps, such as wet etching. This layer may be designed to be resistant to the chemicals used in the etching process, thereby preventing damage to the continuous interconnect layer or other features. Examples of embodiments include layers of nickel, cobalt, or other metals that exhibit selective etching properties when compared to materials like copper.

As used herein, and unless otherwise specified, the term “seed layer” refers to a thin layer, typically 20 nm to 200 nm thick, of material that is deposited onto a substrate to promote the adhesion and growth of subsequently deposited materials, such as metals in an electroplating process. The seed layer serves as a nucleation site for the growth of the continuous interconnect layer. Examples of embodiments include thin films of metals such as copper, nickel, or gold that are deposited by sputtering, evaporation, electroplating, or electroless plating.

As used herein, and unless otherwise specified, the term “barrier layer” refers to a layer of material that is designed to prevent the diffusion of atoms between adjacent layers within a device, thereby preserving the integrity and performance of the device. The barrier layer is (e.g., typically) resistant to intermixing with the materials it separates. Examples of embodiments include layers made of materials such as titanium tungsten (TiW), titanium nitride (TiN), or tantalum nitride (TaN), which are commonly used to prevent the diffusion of metals like copper into silicon or other materials.

As used herein, and unless otherwise specified, the term “connection bumps” refers to raised conductive features on a substrate or layer that are used to establish an electrical connection with corresponding features on another component, such as a die or another substrate. These bumps are typically used in flip-chip or similar packaging technologies to connect a die to a substrate or interposer. Examples of embodiments include bumps made of metals or metal alloys wherein the metals are selected from tin, silver, bismuth, indium, copper, cobalt, and gold, which may be formed by processes such as electroplating, stencil printing, or ball placement.

As used herein, and unless otherwise specified, the term “lift-off process” refers to a method of patterning thin films in which a patterned resist is used to define regions where material deposition is desired before the material is deposited over the patterned resist. After deposition, the resist is removed, “lifting off” the excess material and leaving behind the patterned thin film where openings were present in the resist. Examples of embodiments include the use of photoresist or other types of resist that may be patterned using photolithography, electron beam lithography, or other lithographic techniques, followed by deposition of materials such as metals.

As used herein, and unless otherwise specified, the term “carrier substrate” refers to a temporary support structure used to hold and transport multiple dies or components during the manufacturing process. The carrier substrate aligns the dies in a (e.g., specific) pattern corresponding to the pattern of cavities or connection sites on the device being assembled. Examples of embodiments include silicon wafers, glass plates, or other rigid or flexible materials that may be coated with an adhesive or other means of attachment to temporarily hold the dies in place during processing steps such as die placement and bonding.

The disclosure will now be described by a detailed description of several embodiments of the disclosure. Other embodiments of the disclosure may be configured according to the knowledge of persons skilled in the art without departing from the technical teaching of the disclosure, the disclosure also provided in the appended claims.

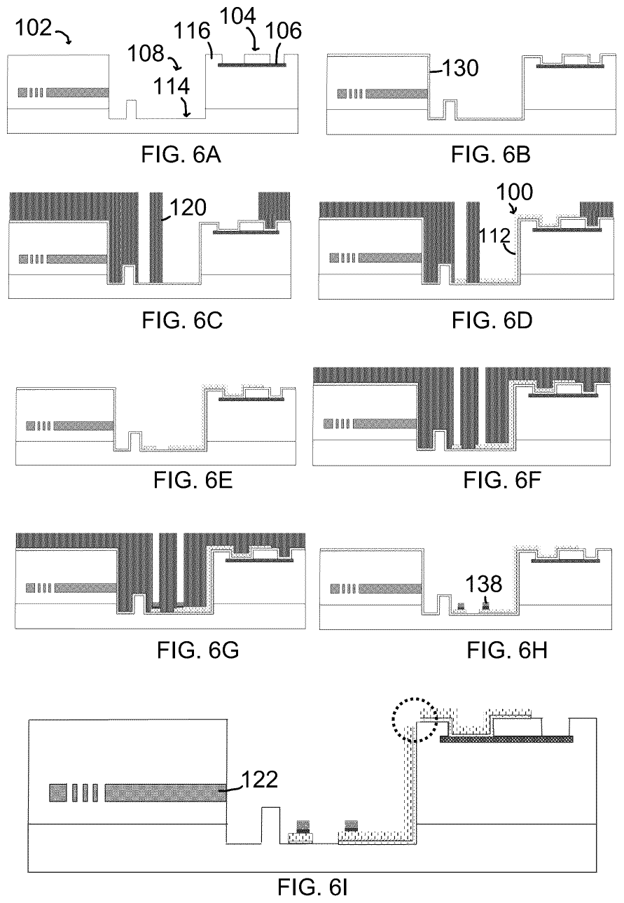

Referring to FIGS. 6A-6I, which shows a series of cross-sectional views illustrating various steps for forming a device (102) according to a first embodiment of the present disclosure. In this embodiment, no electrically conductive protection layer (118) is present on the electrical connection (100). This embodiment provides an alternative to wire bonding and does not require a large cavity (e.g., although it may be too fragile for some processes). The device lacking a protection layer may have limitations, such as potential disconnection (see dashed circle in the last figure of FIG. 6) or damage to the electrical connection (100) during processing.

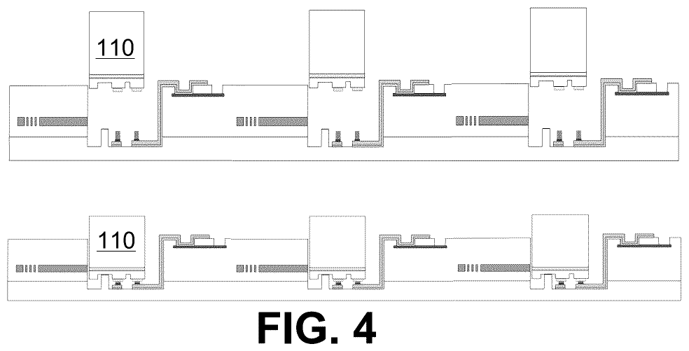

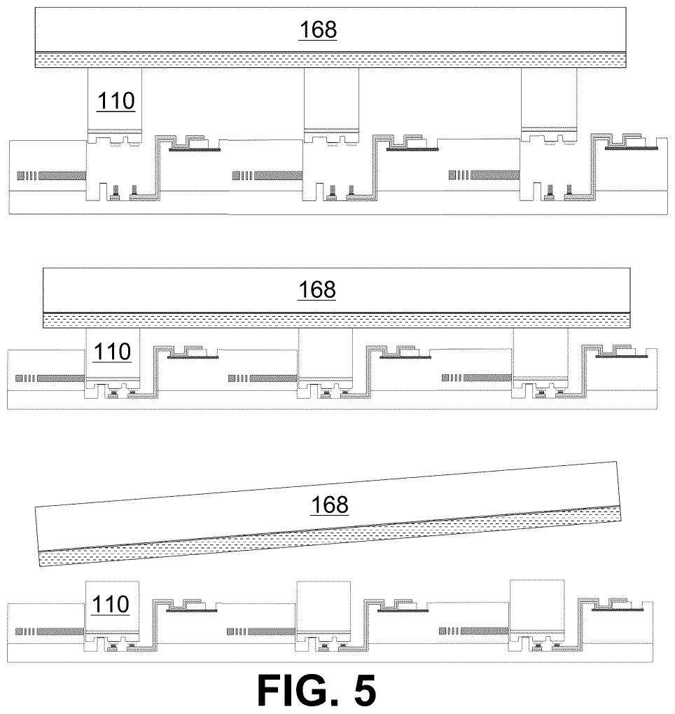

In a first aspect, the present disclosure relates to a method for forming electrical connections (100) in an electro-optic or electronic device (102). As shown in FIG. 6A, the device includes a top surface (104) exposing an electrical path (106) and a cavity (108) in the top surface (104) for housing a die (110). The electrical connections (100) established by the method are suitable for connecting the electrical path (106) and the die (110) (depicted in FIGS. 4 and 5). The method involves forming a continuous interconnect layer (112) that extends from the bottom (114) of the cavity (108), across any topographical features (116), to the electrical path (106). This continuous interconnect layer (112) is useful for providing reliable electrical connections between the die (110) and the circuitry of the device (102).

To facilitate the formation of the continuous interconnect layer (112), the method may include depositing a seed layer (130) on the device (102) prior to forming the continuous interconnect layer (112). This is depicted in FIG. 6B. After forming the electrical connections (100), the seed layer (130) may be etched away, leaving the seed layer (130) only under the electrical connections (100). Additionally, a barrier layer (not depicted) may be deposited before the seed layer (130) to prevent diffusion between the continuous interconnect layer (112) and underlying materials. Suitable materials for the barrier layer include TiW, TiN, or TaN.

In example embodiments, the continuous interconnect layer (112) may include an electrically conductive protection layer (118) designed to prevent disconnection during a wet etch process. This protection layer (118) may comprise a metal with wet etching selectivity to copper, such as nickel or cobalt. The protection layer (118) may have a thickness ranging from 0.1 μm to 3.0 μm, with ranges from 0.2 μm to 2.0 μm, or from 0.3 μm to 1.0 μm, or from 0.3 to 0.7 μm. This provides adequate protection while maintaining the overall conductivity of the interconnect layer (112).

Connection bumps (138) for the die (110) may be formed on the continuous interconnect layer (112) at the bottom (114) of the cavity (108). The formation of these connection bumps (138) may involve creating a patterned mask with openings that expose the continuous interconnect layer (112) only where the bumps (138) may be formed, followed by electroplating a metal through these openings. The material for the connection bumps (138) may include tin, silver, bismuth, indium, copper, cobalt, and gold.

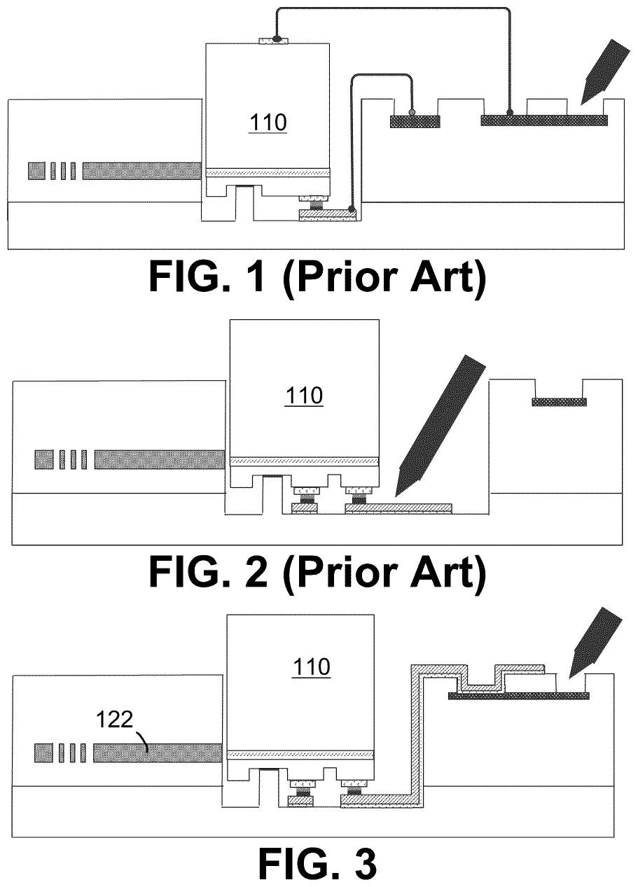

The electrical path (106) is configured to provide electrical or electro-optical tests of the die (110) from the top surface (104), as depicted in FIG. 3. This configuration allows for testing without additional connections and contrasts with the prior art shown in FIG. 1, where wire connections are used, and prior art shown in FIG. 2, which shows direct testing in a large cavity. In example embodiments, the electrical path (106) may comprise aluminum bond pads.

The method may employ a lift-off process for forming the continuous interconnect layer (112), where the material is deposited on a patterned resist and then the resist is removed to leave the interconnect layer (112) only in desired locations.

For devices with multiple cavities (108), the method includes providing a carrier substrate (168) removably attached to the same number of dies (110) arranged in a pattern matching the cavities (108). In example embodiments, the number of cavities may exceed the number of dies attached to the substrate (168). However, at least a subset of the cavities that match the number and the pattern of the dies (110). The dies (110), attached to the carrier substrate (168), are physically contacted with the electronic device (102) so that each die (110) is housed in a cavity (108) and connects electrically with the continuous interconnect layer (112) present at the bottom (114) of the cavity (108). The carrier substrate (168) is then detached from the dies (110), as illustrated in the sequence of top views in FIG. 5, and the top view of the disclosure showing multiple cavities (108) prepared for die attachment in FIG. 4.

The second aspect of the disclosure relates to an opto-electronic or electronic device (102) including a top surface (104) exposing an electrical path (106), a cavity (108) in the top surface (104) for housing a die (110), and a continuous interconnect layer (112) extending from the bottom (114) of the cavity (108), across any topographical features (116), to the electrical path (106). The device (102) may include the same features as described in the method, such as the protection layer (118), barrier layer, connection bumps (138), and the configuration for testing.

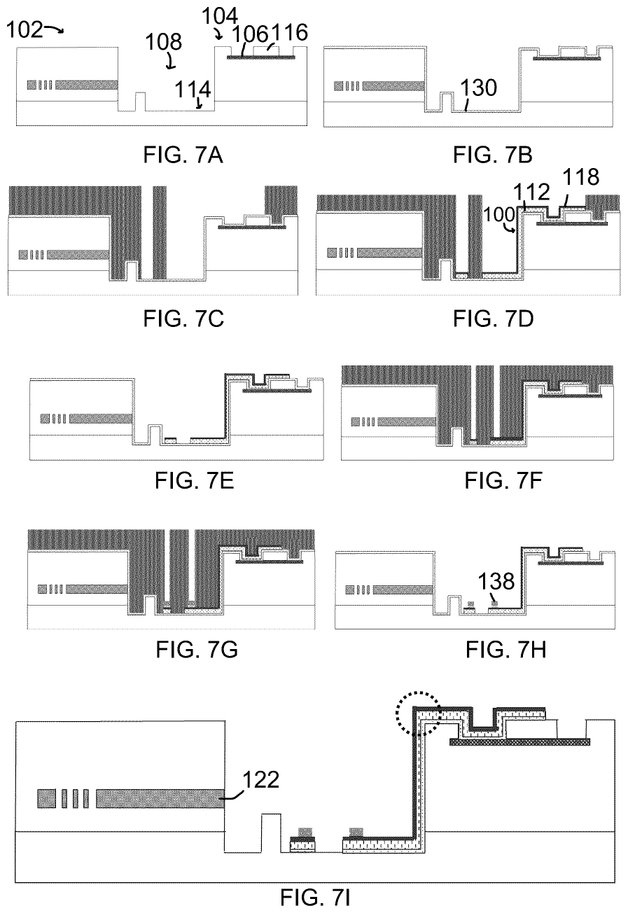

In summary, the disclosure provides a method and device (102) for forming electrical connections (100) that are robust, reliable, and suitable for efficient testing and integration into electronic and electro-optic devices. The inclusion of a protection layer (118), as shown in FIGS. 7A-7I, may offer benefits over the embodiment without such a protection layer (see FIGS. 6A-6I). The device (102) simplifies the testing process and improves the efficiency of die (110) placement and bonding in a patterned array.

### Example 1: Forming Electrical Connections in an Electro-Optic Device without a Protective Nickel Layer

An experiment was conducted to develop a method for forming electrical connections in an electro-optic device. The device comprised a top surface exposing an electrical path and a cavity in the top surface for housing a die. The aim was to create electrical connections suitable for connecting the electrical path and the die, enabling standard electrical and electro-optical testing of the bonded device from the top surface.

This experiment aimed to develop a method for forming reliable electrical connections in an electro-optic device, enabling standard electrical and electro-optical testing of the bonded die from the top surface. The method involves forming a continuous interconnect copper layer instead of using wire bonding.

### Materials and Methods

Electro-optic device with a top surface exposing an electrical path and a cavity for housing a die
Barrier material and deposition equipment
Copper seed layer solution and equipment
Copper plating solution and equipment
Photoresist and lithography equipment
Wet etching solutions for copper indium-tin)

The procedure began with the preparation of the electro-optic device, which involved cleaning, applying a barrier layer, applying a seed layer (130) (see FIG. 6B), and applying a photoresist layer (120).

Subsequently, lithography was applied to define the specific regions designated for the plating of the continuous interconnect layer (112) (see FIG. 6C). This layer, here composed of copper, was strategically designed to traverse from the bottom (114) of the cavity (108), across any present topographical features (116), and extend all the way to the electrical path (106) on the top surface (104) of the device. The deposition of the copper layer (see FIG. 6D) as the interconnect was achieved using specialized copper plating solutions and equipment. The photoresist (120) was then removed (see FIG. 6E).

The next phase of the procedure involved another application of lithography (see FIG. 6F), this time with the objective of delineating the regions for the plating of connection bumps (138) at the bottom (114) of the cavity. These connection bumps were plated using suitable solder materials, providing a reliable point of contact for the die (110) within the cavity (see FIG. 6G). Once the connection bumps were plated, the photoresist was removed (see. FIG. 6G), and a series of cleaning steps were undertaken to maintain the integrity of the newly plated layers. The seed layer (130) was then removed by wet etching. A thinning of the copper layer was observed during the removal of the seed layer. In one run of the experiment, some parts of the coating were damaged, in particular at the corners (see FIG. 8).

By carefully controlling the exposure time to the etching solution, these drawbacks may be avoided.

The experimental findings highlighted several improvements using the developed method. Firstly, it eliminated the need for wire bonding or large cavities for probing inside the cavity to contact the bonded device. Secondly, it allowed for standard electrical and electro-optical measurements using aluminum bond pads on the top surface, without the need to contact the copper layer directly. Lastly, the use of a one-time barrier/seed layer for (e.g., both) the interconnect and bump plating steps streamlined the fabrication process.

### Example 2: Forming Electrical Connections in an Electro-Optic Device with a Protective Nickel Layer

This experiment, depicted in FIGS. 7A-7I, aimed to develop a method for forming reliable electrical connections in an electro-optic device, enabling standard electrical and electro-optical testing of the bonded die from the top surface. The method involves plating a continuous interconnect layer with a protective nickel coating (118) (see FIG. 7D) to prevent damage sometimes observed in experiment 1 during the wet etch process, and improve reliability.

### Materials and Methods

Electro-optic device with a top surface exposing an electrical path and a cavity for housing a die
Barrier material and deposition equipment
Copper seed layer solution and equipment
Copper plating solution and equipment
Nickel plating solution and equipment
Photoresist and lithography equipment
Wet etching solutions for copper and nickel indium-tin)

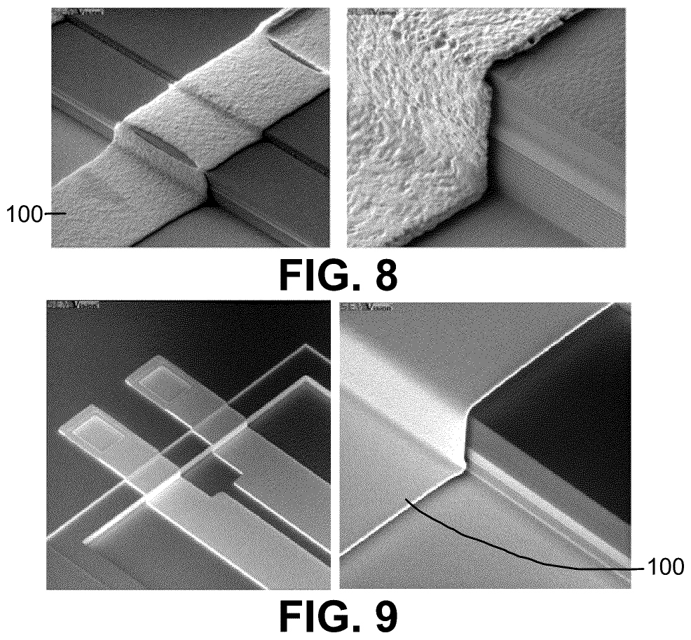

The procedure was the same as for example 1 except that, following the copper plating, a thin nickel layer, with a thickness of approximately 0.5 μm, was plated directly on top of the copper layer, without the removal of the photoresist layer that was previously applied. Nickel was chosen due to its good wet etching selectivity to copper. This plating process, facilitated by nickel plating solutions and equipment, aimed to introduce an electrically conductive protection layer (118) over the copper, which would serve as a safeguard during subsequent processes. With the nickel layer in place, the photoresist was then removed, and a wet etch process was initiated to selectively remove the copper seed layer. The results showed that the nickel layer (e.g., effectively) protected the copper during the wet etch process, preventing disconnection and proving a smooth copper surface (see circled area in FIG. 71 and see FIG. 9).

In conclusion, the experiment (e.g., successfully) demonstrated a method for forming reliable electrical connections in electro-optic devices. By plating a continuous interconnect layer with a protective nickel coating, the method overcame the limitations of previous approaches and provided efficient testing of the bonded device from the top surface. The findings have positive implications for improving the manufacturing and testing processes of electro-optic devices, leading to enhanced reliability and performance.

### Example 3: Bonding a Die in the Device of Example 2

Referring to FIGS. 3 and 4, a die (110) was bonded to the connection bumps within the cavity illustrated in FIG. 7I by utilizing bonding equipment designed for such a task. This step provided the securing of the die within the cavity, proving both proper alignment and a robust connection. To conclude the (e.g., comprehensive) procedure, electrical and electro-optical tests were conducted on the bonded die, leveraging the electrical path (106) on the top surface (104) to evaluate the effectiveness of the connections and the overall performance of the electro-optic device (102).

The experiment demonstrated that the nickel layer acted as a barrier between the copper and the bonded die. During bonding, molten tin from the solder may squeeze out and come into contact with the copper, leading to reliability issues. The presence of the nickel layer prevented direct contact between tin and copper, improving the processing and reliability performance of the device.

### Example 4: Wafer-Level Bonding of Dies in Patterned Cavities

Referring to FIG. 5, this experiment intends to showcase a technique for wafer-level bonding of dies (110) within patterned cavities of an electronic device. The process involves a carrier substrate (168) with dies attached in a matching pattern to the device's cavities, proving electrical continuity between the dies and the interconnect layer within the cavities, followed by the detachment of the carrier substrate.

The procedure begins by preparing an electronic device that features a top surface designed with a series of cavities, each serving as a precise placement point for dies. These cavities are not just structural elements but are integrated with a continuous interconnect layer that extends from the bottom of each cavity to the device's top surface, a configuration that may be achieved as illustrated in examples 1 or 2. To facilitate this intricate assembly, a carrier substrate is utilized, onto which the dies are meticulously arranged in a pattern that mirrors the cavity layout on the device.

The core of the process involves aligning the carrier substrate, with its precisely arranged dies, above the electronic device. For example, passive alignment structures are employed. This alignment provides that each die, guided by the passive alignment structures, is (e.g., perfectly) positioned over its corresponding cavity. Following this precise alignment, the substrate is carefully lowered, allowing each die to make contact with and be housed within its designated cavity. This is where the bonding equipment comes into play, securing each die to the interconnect layer within its cavity, providing a robust and reliable connection.

Once the dies are securely bonded within the cavities, the next step involves the delicate removal of the carrier substrate. This step is executed with precision, proving that the now bonded dies remain intact within their cavities. Following this, a thorough cleaning process is conducted, accompanied by an inspection phase to provide that each die is correctly aligned within its cavity and that the electrical connections are established as intended.

The outcome of this designed procedure is the (e.g., successful) wafer-level bonding of dies within the patterned cavities of the electronic device. This not only provides that the dies are securely housed within their respective cavities but also guarantees that they are in contact with the interconnect layer, facilitating the necessary electrical connections. The ease with which the carrier substrate may be removed post-bonding is a testament to the efficiency of this method. Ultimately, this approach to the wafer-level integration of dies into electronic devices provides a streamlined assembly process while enhancing the overall performance of the devices. It is to be understood that although example embodiments, specific constructions and configurations, as well as materials, have been discussed herein for devices according to the present disclosure, various changes or modifications in form and detail may be made without departing from the scope of this disclosure. For example, any formulas given above are merely representative of procedures that may be used. Functionality may be added or deleted from the block diagrams and operations may be interchanged among functional blocks. Steps may be added or deleted to methods described within the scope of the present disclosure.

While some embodiments have been illustrated and described in detail in the appended drawings and the foregoing description, such illustration and description are to be considered illustrative and not restrictive. Other variations to the disclosed embodiments may be understood and effected in practicing the claims, from a study of the drawings, the disclosure, and the appended claims. The mere fact that measures or features are recited in mutually different dependent claims does not indicate that a combination of these measures or features cannot be used. Any reference signs in the claims should not be construed as limiting the scope.

What is claimed is:

1. A method for forming electrical connections in an electro-optic or electronic device comprising:
a top surface exposing an electrical path; and
a cavity in the top surface, the cavity housing a die, the electrical connections configured to connect the electrical path and the die, wherein forming the electrical connections includes forming an interconnect layer extending from a bottom of the cavity, across topographical features, to the electrical path.

2. The method according to claim 1, wherein the interconnect layer is substantially continuous.

3. The method according to claim 1, wherein the interconnect layer includes an electrically conductive protection layer configured to prevent disconnection in the interconnect layer during a wet etch process.

4. The method according to claim 3, wherein the interconnect layer is provided in the form of copper.

5. The method according to claim 4, wherein the electrically conductive protection layer includes a metal with wet etching selectivity to copper.

6. The method according to claim 5, wherein the metal of the electrically conductive protection layer is nickel or cobalt.

7. The method according to claim 2, wherein the electrically conductive protection layer has a thickness from 0.1 μm to 3.0 μm, or from 0.2 μm to 2.0 μm, or from 0.3 μm to 1.0 μm, or from 0.3 μm to 0.7 μm.

8. The method according to claim 1, further comprising depositing a seed layer on the device prior to forming the interconnect layer, and etching the seed layer after the forming of the electrical connections to leave the seed layer under the electrical connections and remove the remaining seed layer.

9. The method according to claim 1, further comprising forming connection bumps for the die on the interconnect layer on the bottom of the cavity.

10. The method according to claim 1, wherein the electrical path is configured to provide electrical or electro-optical tests of the die.

11. The method according to claim 1, wherein the top surface includes a number of cavities for housing a die, wherein the number of cavities form a pattern.

12. The method according to claim 11, further comprising:
providing a carrier substrate removably attached to a same number of disarranged in this same pattern,
physically contacting the dies, attached to the carrier substrate, with the electronic device, wherein each die is housed in a cavity and connects electrically with the interconnect layer at the bottom of the cavity, and
detaching the carrier substrate from the dies.

13. An electro-optic or electronic device comprising:
a top surface exposing an electrical path,
a cavity in the top surface for housing a die, and
a interconnect layer extending from a bottom of the cavity, across topographical features, to the electrical path.

14. The device according to claim 13, wherein the interconnect layer includes a protection layer.

15. The device according to claim 14, wherein the protection layer includes a metal with wet etching selectivity to a material of the interconnect layer.

16. The device according to claim 15, wherein the interconnect layer is made of copper, and the metal of the protection layer is nickel or cobalt.

17. The device according to claim 13, wherein the electrically conductive protection layer has a thickness from 0.1 μm to 3.0 μm, or from 0.2 μm to 2.0 μm, or from 0.3 μm to 1.0 μm, or from 0.3 μm to 0.7 μm.

18. The device according to claim 13, further comprising connection bumps for the die on the interconnect layer on the bottom of the cavity.

19. The device according to claim 13, wherein the electrical path is configured to provide electrical or electro-optical tests of the die.

20. The device according to claim 19, the electrical or electro-optical tests are performed from the top surface.
